(19) United States
(12) Patent Application Publication
(10) Pub. No.: US 2026/0040969 A1
(43) Pub. Date: Feb. 5, 2026

(54) INDUCTION-BASED INTER-CHIP COMMUNICATION

(71) Applicant: Intel Corporation, Santa Clara, CA (US)

(72) Inventors: Shamsul ABEDIN, Portland, OR (US); Stephen MOREIN, San Jose, CA (US); Tina C. TOUPAL, Portland, OR (US); Zhen ZHOU, Chandler, AZ (US)

(21) Appl. No.: 19/358,452

(22) Filed: Oct. 15, 2025

Related U.S. Application Data
(60) Provisional application No. 63/827,046, filed on Jun. 20, 2025.

(51) Int. Cl. H01L 23/538; H01L 21/66; H01L 25/18; H10B 80/00

(52) U.S. Cl. CPC H01L 23/5384; H01L 22/12; H01L 25/18; H10B 80/00; H01L 2225/06541; H01L 2225/06596

(57) ABSTRACT

Various aspects relate to electronic memory devices and mechanisms for communicating with electronic memory devices. A plurality of stacked semiconductor wafers forms a wafer stack. A logic base die is configured to support the plurality of stacked semiconductor wafers. At least one through silicon via is formed through the plurality of stacked semiconductor wafers, wherein the at least one through silicon via is configured to form an inductive coil that is configured to provide a communication interface to the plurality of stacked semiconductor wafers.

### CROSS-REFERENCE TO RELATED APPLICATION

This application claims priority to U.S. Provisional Patent Application No. 63/827,046 filed on Jun. 20, 2025, the contents of which is fully incorporated herein by reference.

### BACKGROUND

Memory devices are key components in any electronic system, as memory devices enable storage of data and instructions for the operation of electronic systems. In view of an increasingly data intensive nature of modern applications and in particular artificial intelligence applications, memory operations (e.g., to write data into a memory, or to read data from a memory) have a significant influence on the overall performance of an electronic system. Thus, strategies for providing resource efficient memory operations are of particular interest for the further development and testing of modern devices as well as providing an ability to locate memory proximate to central processing units, graphical processing units, and artificial intelligence accelerator application specific integrated circuits.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the proposed configuration. In the following description, various aspects are described with reference to the following drawings, in which:

FIG. 1A illustrates an exemplary slice formed by stacking dram wafers. Multiple slices can be stacked with associated vertical inductors, referred to as a cube, that can be used to communicate between chips, i.e., a cube and a host die;

FIG. 1B shows an exemplary integrated circuit device or module including a processor, a glass substrate, and a plurality of cubes on their respective host dies with a plurality of connectors contained within an integrated circuit package;

FIG. 2 shows an exemplary formation of vertical inductor coils using through silicon vias and vertical inductors that can be used use as chip interface to communicate between two components of an integrated circuit;

FIG. 3A shows an exemplary inductive coil that is formed using a single row of vertical vias connecting the vias using a redistribution layer connecting directly to a vertical via pad;

FIG. 3B shows another exemplary inductive coil that is formed using a single row of vertical vias by connecting those vertical vias through redistribution layer landing vias and redistribution layer lateral interconnections on top of a vertical via pad with an additional small via down to the vertical via;

FIG. 4A shows an exemplary inductive coil having a current path that uses four vertical vias in a row and three vertical via rows that are connected using a single redistribution layer at the top and single redistribution layer at bottom ends of the vias;

FIG. 4B shows another exemplary inductive coil having four vertical vias in a row with three such vertical via rows being connected through two redistribution layers at the top end and bottom end of the vertical vias;

FIG. 5A shows an exemplary array of inductor coils for a data interface scheme, where two-dimensional inductor coil arrays can be formed by stacking inductors of stacked dies;

FIG. 5B shows an exemplary active coil and non-active coil that can be configured for parallel loop back to test the inductor coils, during a manufacturing test;

FIG. 5C shows another exemplary active coil and non-active coil that can be configured in a series chain loopback configuration to test the inductor coils health, during a manufacturing test;

FIG. 6A shows the construction of a dummy coil using a single row of vertical vias that is connected using a redistribution layer on top and bottom of the vias to form the dummy coil;

FIG. 6B illustrates exemplary dummy inductive coils in loopback configuration in which the normal functional transmit analog front end drives the functional coil and the dummy coil connected to a dummy receiver that is turned off during functional mode.

FIG. 6C illustrates how another exemplary dummy transmit driver drives the dummy inductor coil and the functional receiver connected to the functional coil detects the pattern during manufacturing tests;

FIG. 7 shows a stacked wafer cross section providing vias through stacked wafers manufactured in a particular semiconductor fabrication plant and stacked together;

FIG. 8 shows various arrangements of smaller diameter coils that can be coupled to a larger diameter coil in another integrated circuit or substrate;

FIGS. 9-15 show further arrangements of smaller diameter coils on a host substrate that can be coupled with to receive inductive signals from a larger diameter coil in another integrated circuit such as a three-dimensional memory cube;

FIG. 16 shows further arrangements of smaller diameter coils on a host substrate that can be selectively activated to transmit to a larger diameter coil in another integrated circuit such as a three-dimensional memory cube;

FIG. 17A shows a two-dimensional rendering of an exemplary formation of inductor coils using through silicon vias and vertical inductors that can be used use as a platform-to-chip interface to communicate with three-dimensional integrated circuits with offset platform inductors;

FIG. 17B shows a three-dimensional rendering of an exemplary formation of inductor coils using through silicon vias and vertical inductors that can be used use as a platform-to-chip interface to communicate with three-dimensional integrated circuits with offset inductors in a planar host die;

FIGS. 18A to 18C show three-dimensional renderings of exemplary formation of inductor coils using through silicon vias and vertical inductors that can be used use as a platform-to-chip interface to communicate with three-dimensional integrated circuits using a coil inductor in a planar host die;

FIGS. 19A to 19C show three-dimensional renderings of exemplary formation of inductor coils using through silicon vias and vertical inductors that can be used use as a platform-to-chip interface to communicate with three-dimensional integrated circuits using a coil inductor in a planar host die;

FIG. 20 shows a block diagram representing a mechanism for selecting a smaller coil in a receive-side inductive inter-chip communication system using a signal strength detect circuit; and

FIG. 21 shows three layers of inductor coils in an exemplary planar host die.

### DESCRIPTION

The following detailed description refers to the accompanying drawings that show, by way of illustration, specific details and aspects in which the proposed configuration may be practiced. These aspects are described in sufficient detail to enable those skilled in the art to practice the proposed configuration. Other aspects may be utilized and structural, logical, and electrical changes may be made without departing from the scope of the proposed configuration. The various aspects are not necessarily mutually exclusive, as some aspects may be combined with one or more other aspects to form new aspects. Various aspects are described in connection with methods and various aspects are described in connection with devices (e.g., a memory module, a computing system). However, it is understood that aspects described in connection with methods may apply in a corresponding manner to the devices, and vice versa.

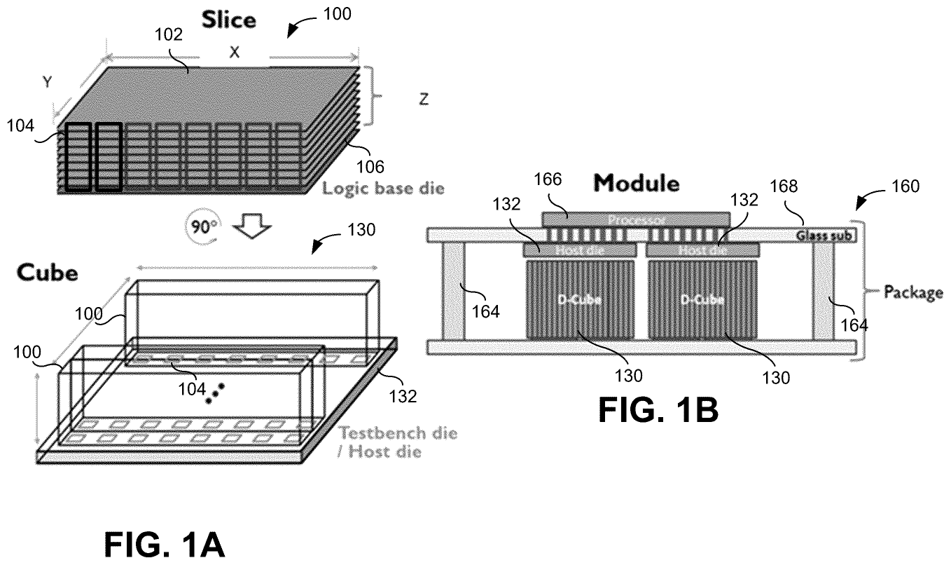

FIG. 1A illustrates an exemplary slice 100 formed by stacking dram wafers 102 with associated vertical inductors 104 that can be used to communicate between chips as well as cube 130, which is an assembly of slices 100 on host die 132. Advanced applications such as artificial intelligence-centric applications demand more memory access around computing units such as central processing units (CPU), graphical processing units (GPU), and artificial intelligence (AI) accelerator application-specific integrated circuits (ASIC) (all of which may be generally referred to as XPU). The arrangement shown in FIG. 1 may provide for increased memory capacity in artificial intelligence applications, for example. Associated stacked memory chiplets may be rotated 90 degrees to form a Z Axis Memory stack (ZAM). In this arrangement, communication between the stacked memory dies and an associated host die is compact and everything is within a short distance. In addition, by using inductive coupling as a communication mechanism, an associated interface becomes contactless. On a host side, planar inductors can be fabricated. On the stacked memory side, various aspects for providing communication inductors are disclosed herein. In some embodiments, memory management, including address decoding and mapping may be performed by memory management logic contained within logic base-die 106.

In various embodiments, stacking and bonding multiple wafers (or chiplets) can significantly enhance logic and memory density of an integrated circuit. A chiplet is a small, modular, and independently testable unit of a larger integrated circuit, designed to be combined with other chiplets to create a more complex system. Vertical vias that run through such layered wafers create connections between stacked dies. These vertical vias through the stacked dies can create vertical inductors by connecting the top and bottom ends using redistribution layers (RDL), which inductors can be used to provide an inductive interface of such a memory chip. Additionally, a single thick die with through silicon vias (TSV) can connect a top and bottom using RDLs to form vertical multi-turn inductor coils. Such an approach allows associated chiplets to interface through chiplet edges using vertical inductor coils.

FIG. 1B shows an exemplary integrated circuit module including processor 166, glass substrates 168 and substrate 162, and a plurality of cubes 130 on their respective host dies 162 with a plurality of connectors contained within an integrated circuit package 160. In some embodiments, processor 160 may be any type of an XPU that can interface with the highly performant and densely-packed dynamic random-access memory provided in package 160. In some such embodiments processor 166 interfaces with the memory device wirelessly via inductors in host dies 132. In these embodiments, it is possible to non-destructively perform manufacturing tests on arbitrary types of XPU using the memory. In these approaches, it is possible to sell the XPU separately from memory, for example if a customer would like to obtain the customer's memory separately or simply if the XPU and memory devices should be stored and/or shipped separately.

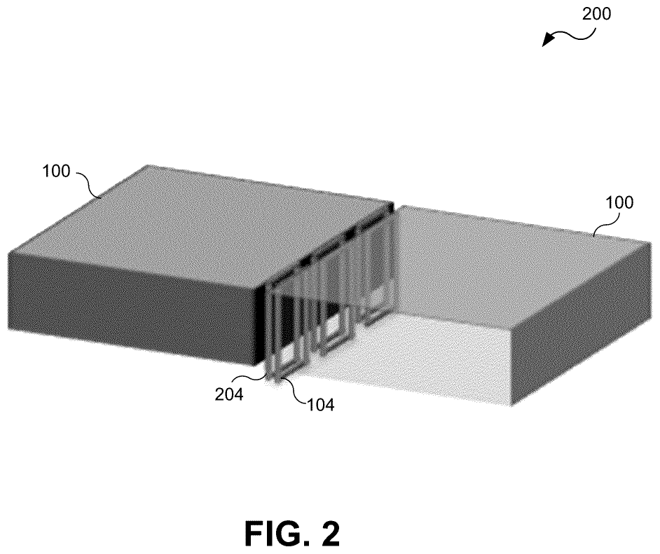

FIG. 2 shows an exemplary formation of vertical inductor coils using through-semiconductor vias (or more specifically through-silicon vias) and vertical inductors that can be used as an integrated circuit interface to communicate between two integrated circuits 100. As long as each component has an inductor 104 that is within range of an associated paired inductor 204, logical operations can be carried out between the two components 100 as if the paired inductors made up a communicating electrical connection in a digital system. That is to say an activated inductor can be considered as a logical ‘1’ and a deactivated inductor as a logical ‘0’ or vice versa, in the case of inverted logic. A clock signal can provide timing, which clock signal may involve an electrical connection between components 100 or a clock signal may be provided via paired inductors analogously to the digital signals themselves. In some other embodiments, components 100 have integrated internal clocks that need be only initially or periodically synchronized. In some embodiments, this functionality may be provided in connection with a vertical inductor in a thick die and facing each other for interface using a corresponding vertical inductor.

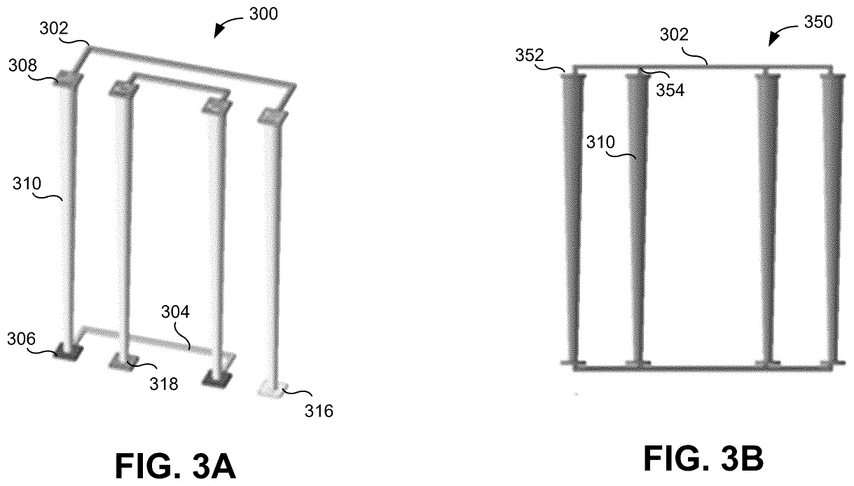

FIG. 3A shows an exemplary inductive coil 300 that is formed using a single row of vertical vias 310 and connecting the vias 310 using a redistribution layer connecting directly to vertical via pads 306. In various aspects, one way of designing vertical inductors is to use a single row of vias as shown. A loop path can be observed starting at via pad 316 continuing up to redistribution layer trace 302 continuing down via 310 to pad via 306 along redistribution layer trace 304 back up the via adjacent to via 310 and finally back down to pad 318.

FIG. 3B shows another exemplary inductive coil 352 that is formed using a single row of vertical vias by connecting those vertical vias through redistribution layer landing vias and redistribution layer lateral interconnections on top of a vertical via pad with an additional small via down to vertical via 310. In some embodiments vias may be connected to form loops or coils using traces from any number of metal layers.

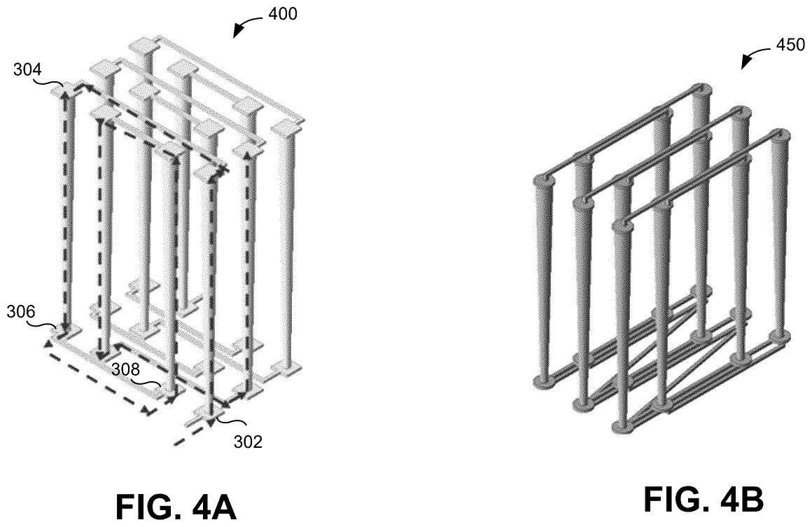

FIG. 4A shows an exemplary inductive coil having a current path that uses four vertical vias in a row and three vertical-via rows that are connected using a single redistribution layer at the top and single redistribution layer at bottom ends of the vias. In some embodiments, multiple vertical via rows with either single or multiple redistribution layers to form multi-turn inductor coils. In these embodiments, one of the vertical coils may be formed using a single redistribution layer and multiple vertical via rows, and each row has multiple vertical vias. In this approach, a redistribution layer is connected directly to via pads 302 306 and 308 and form a coil of multiple turns by connecting the vias top and bottom as show in coil 400.

FIG. 4B shows another exemplary inductive coil having four vertical vias in a row with three such vertical via rows being connected through two redistribution layers at the top end and bottom end of the vertical vias. In some embodiments vias in multiple rows may be connected to form loops or coils using traces from any number of metal layers.

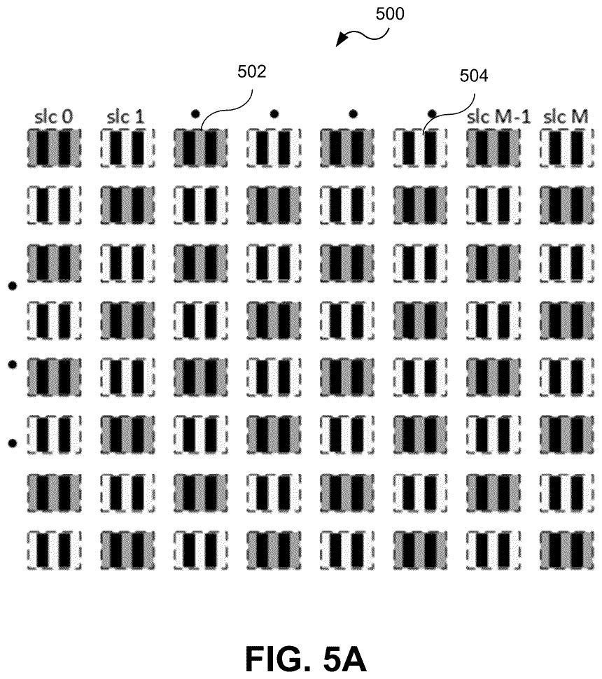

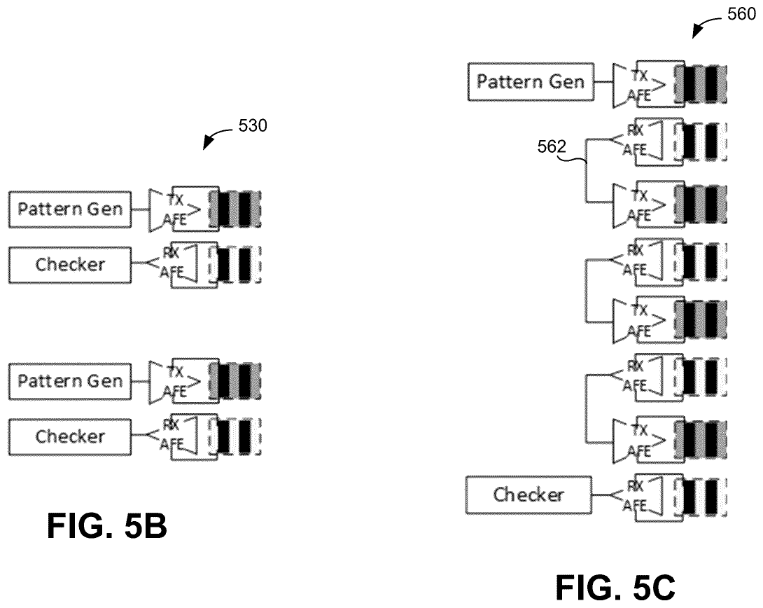

FIG. 5A shows an exemplary array 500 of inductor coils for a data interface scheme, where two-dimensional inductor coil arrays can be formed by stacking inductors of stacked dies in a checkerboard configuration. The dark shapes (labeled 502) are the active inductor coils during functional data transactions, and the light shapes (labeled 504) are turned off or non-active coil to avoid cross talk. When using an inductor coil interface, adjacent coils generally introduce crosstalk, which decreases the reliability of data transfer between two chips. To increase reliability, one method is to keep turning off the adjacent coils, thus preventing cross-talk-induced coupling. By applying a checkerboard pattern (as shown in array 500) on adjacent vertical inductor coils, e.g., within the same slice or in neighboring slices, the health of the inductor coils can be assessed in a loopback configuration during manufacturing tests.

FIG. 5B shows an exemplary active coil and non-active coil that can be configured for parallel loop back to test the inductor coils, during a manufacturing test. During manufacturing test, the active coil and the non-active coil can be configured for parallel loop back to test the inductor coils. Dummy inductor coils from additional rows of vias adjacent to the functional vertical inductor are activated in the loopback mode to determine the health of the functional vertical inductors.

FIG. 5C shows another exemplary active coil and non-active coil that can be configured in a series chain loopback configuration to test the inductor coils health, during a manufacturing test. During a manufacturing test the active coil and the non-active coil can be configured in a series chain loopback configuration to test the inductor coils health.

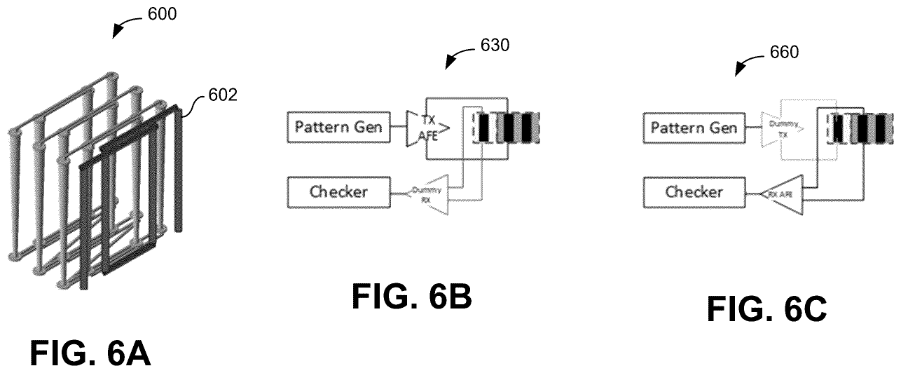

FIG. 6A shows an exemplary shows the construction of a dummy coil 602 using a single row of vertical vias that is connected using a redistribution layer on top and bottom of the vias to form the dummy coil. In some embodiments, a dummy coil may be used in connection with logic bas-die 106 of FIG. 1 to receive self-generated transmit signals in a loop-back configuration for manufacturing testing.

FIG. 6B illustrates exemplary dummy inductive coils in which a normal functional transmit analog front end drives the functional coil and the dummy coil connected to a dummy receiver that is disabled during functional mode of the semiconductor, i.e., when the semiconductor is being used in production as compared to manufacturing testing. In loop-back configuration mode the inductor coil can be tested during manufacturing tests. This figure illustrates that a normal functional transmit analog front end drives the functional coil and the dummy coil connected to a dummy receiver that is turned off during a functional mode. In loop-back configuration the inductor coil can be tested during manufacturing tests.

FIG. 6C illustrates another exemplary dummy transmit driver that drives the dummy inductor coil and the functional receiver connected to the functional coil may detects a predefined pattern during manufacturing testing.

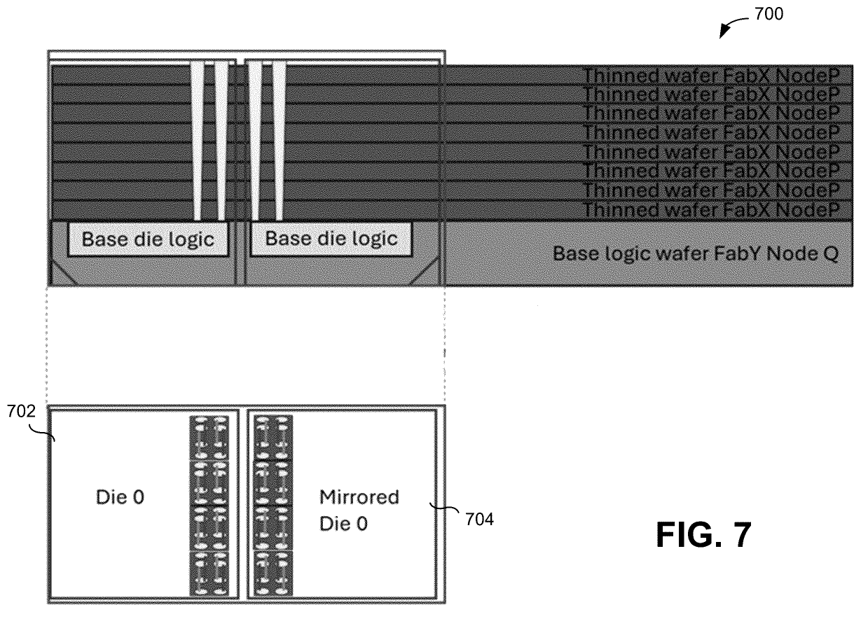

FIG. 7 shows an exemplary stacked wafer cross section 700. Through semiconductor vias through the stacked wafers manufactured in a particular semiconductor fabrication plant are stacked together. The stacked wafers can be either logic or memory wafers as part of another stacked three-dimensional chip. The base die 702 can be fabricated in a different process node at a different semiconductor fabrication plant. Such a base die can function as the controller logic for the stacked wafers. The via through the stacked wafers connects to the logic base die wafer where the analog front-end circuits are implemented to transmit and receive signals through the inductor coils. The adjacent dies are placed as mirror of each other, i.e., with mirrored die 704 placed adjacent to based die 702 as shown, within the reticle, so the inductors formed by the vias face each other and are electromagnetically coupled. During manufacturing testing, the analog front-end circuit on both dies are configured in loop back mode to test the health of the coils. In some such embodiments, adjacent dies may be placed in mirrored position within a reticle, so that vertical inductors face each other and can couple together to form an inductive channel at the wafer stack. A wafer level loopback test can then be performed to verify early health of the inductors before die singulation.

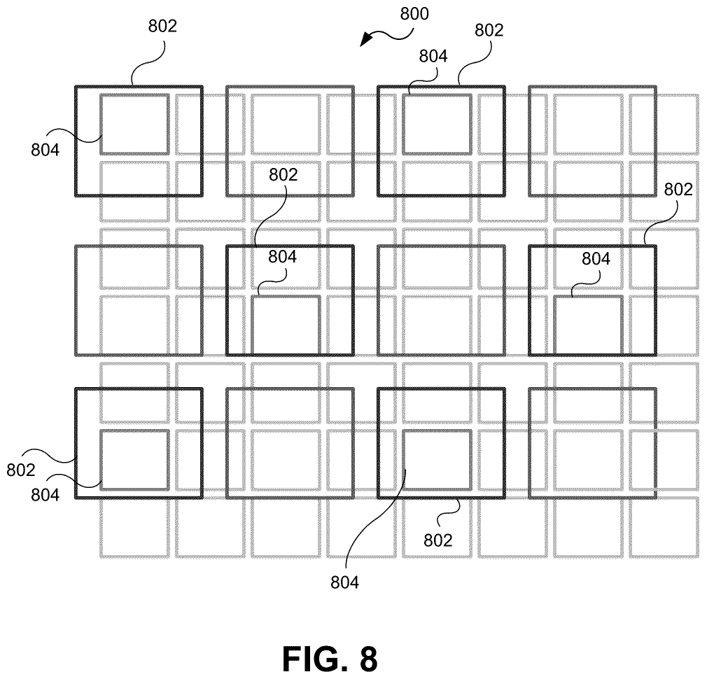

FIG. 8 shows various possible arrangements of smaller diameter coils that can be coupled to a larger diameter coil in another chip. Even if there is misaligned placement of the two chips, at least one of the smaller coils (see e.g., coil 804) will be fully enclosed within the larger diameter coil 802 which gives the strongest coupling. By selecting the strongest coupled coil of the smaller diameter coil array, the channel will have enhanced reliability with relaxed alignment requirements for the coils of the two communicating chips. To ensure reliable data transfer through the inductive coupling channel, it is beneficial for the inductors on the two dies to be well aligned. By implementing multiple smaller inductor coils on one of the dies and selecting a coil with strong coupling, reliability of the channel can be significantly improved. This method reduces the alignment tolerance requirements between the two dies.

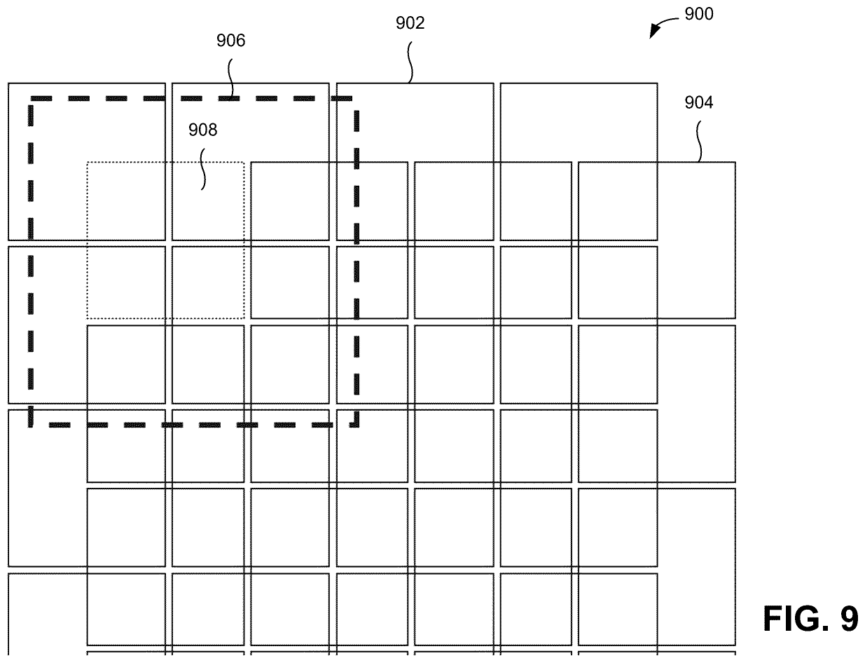

FIGS. 9-15 show further arrangements of smaller diameter coils on a host substrate that can be coupled to receive inductive signals from a larger diameter coil in another integrated circuit such as a three-dimensional memory cube. As shown throughout FIGS. 9-15, a generally larger dashed square represents a larger set of inductors representative of the plurality of inductors that would be found on memory cubes in various aspects. Non-dashed squares in these figures generally represent inductive coils on a host die, such as a host substrate or other circuit that may be configured to connect to memory cubes. When the physical memory cubes are placed onto a host substrate, there may be various misalignments that may manifest themselves in ways that likely cannot be known in advance. Accordingly, in various aspects, mechanisms are provided to identify which inductor has the best signal and using that inductor accordingly. Generally speaking, a smaller receiving inductor that is entirely within a transmitting inductor will receive a relatively better signal than a receiving inductor that is not entirely within the transmitter. In some embodiments a most central receiving inductor should be chosen. In some embodiments, analog circuitry may be emplaced within a host platform to determine which is the strongest signal by, for example, measuring an induced current in a receiving coil with an analog to digital converter or using other mechanisms for measuring received inductive signal strength. In some embodiments, employing overlapping inductor coils on the receiving side of the inductive communication path allows greater flexibility in selecting an inductor with which to receive a signal.

FIG. 9 shows a so-called 50 percent pattern on the host, receiver side. Inductor patterns 902 and 904 are shifted by 50% in both horizontal and vertical directions to provide flexibility in identifying a relatively centered coil within the transmitting coil 906. In this case, coil 908 shown with a partially dashed line is relatively centered within coil 906 and therefore receiving coil 908 would be a good candidate receiving coil to be selected to receive a signal from a transmitting device such as a memory cube.

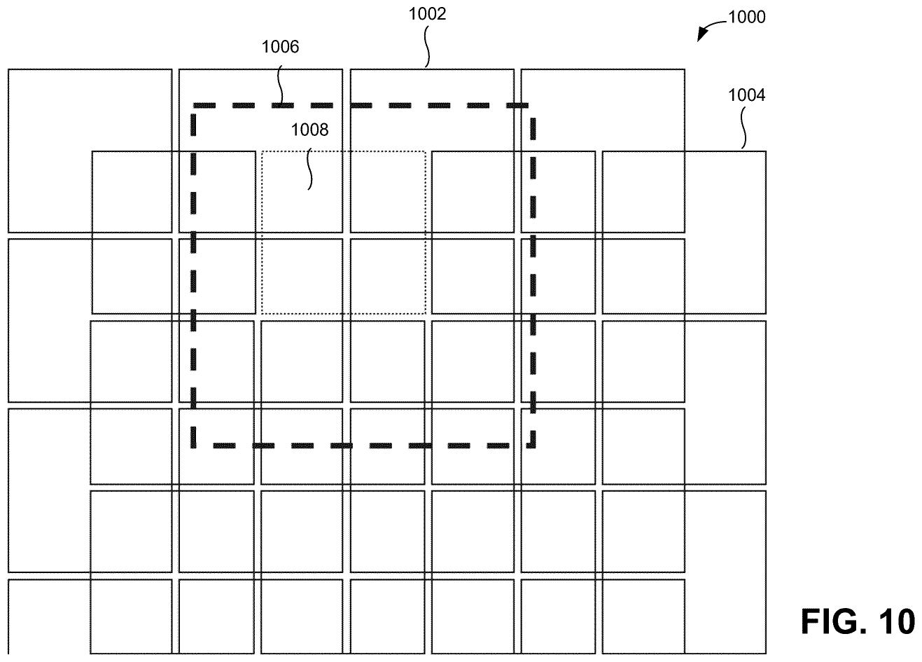

FIG. 10 shows another so-called 50 percent pattern on the host, receiver side. Inductor patterns 1002 and 1004 are again shifted by 50% in both horizontal and vertical directions to provide flexibility in identifying a relatively centered coil within the transmitting coil 1006 which evidences a significant misalignment. In this case, coil 1008 shown with a partially dashed line is relatively centered within coil 1006 and therefore receiving coil 1008 would be a good candidate receiving coil to be selected to receive a signal from a transmitting device such as a memory cube.

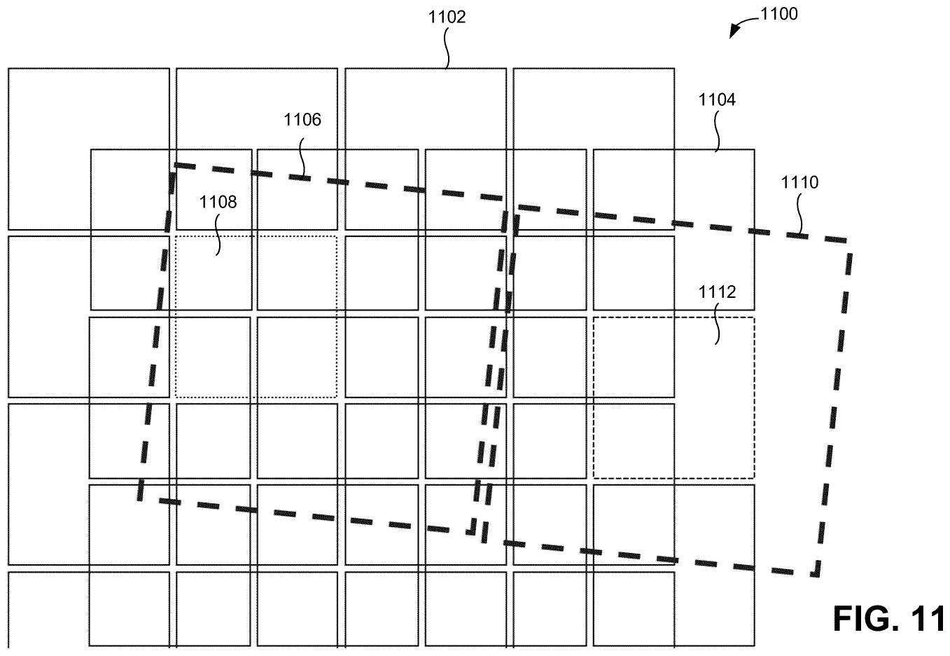

FIG. 11 shows yet another so-called 50 percent pattern on the host, receiver side. Inductor patterns 1102 and 1104 are again shifted by 50% in both horizontal and vertical directions to provide flexibility in identifying a relatively centered coil within the transmitting coil 1106 and adjacent coil 1110, both of which evidence a significant misalignment, including a clockwise rotation. In this case, coils 1108 and 1112 shown with a partially dashed line are relatively centered within coils 1106 and 1110 and therefore receiving coils 1108 and 1112 would be good candidate receiving coils to be selected to receive signals from a transmitting device such as a memory cube.

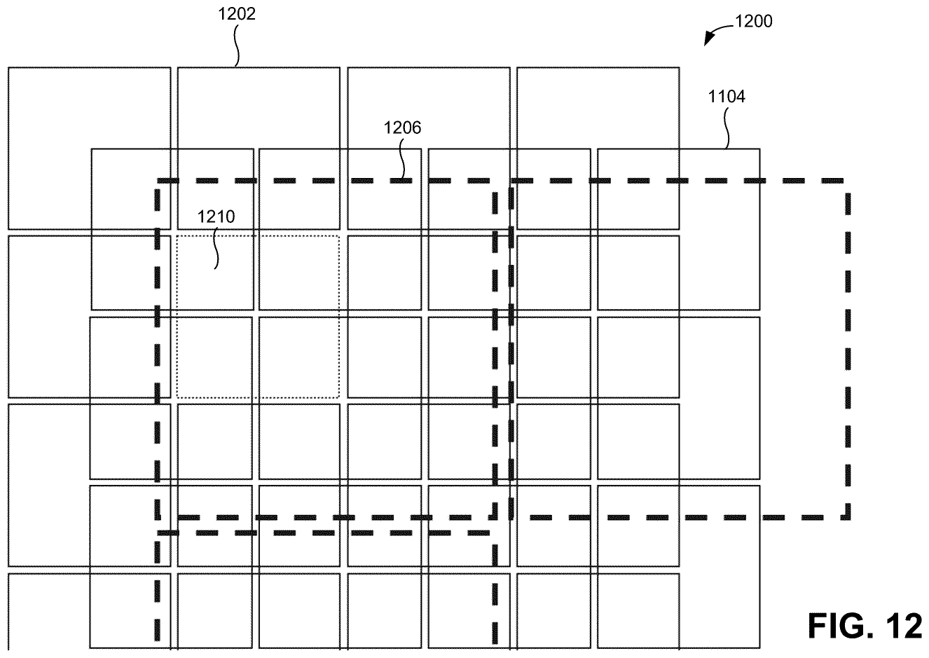

FIG. 12 shows yet another so-called 50 percent pattern misalignment. In this case, coil 1210 shown with a partially dashed line is relatively centered within coil 1206 and therefore receiving coil 1206 would be a good candidate receiving coil to be selected to receive a signal from a transmitting device such as a memory cube. Even though coil 1210 is not truly centered within coil 1206, it is nevertheless within the perimeter of coil 1206 and therefore the best candidate for a receiving coil.

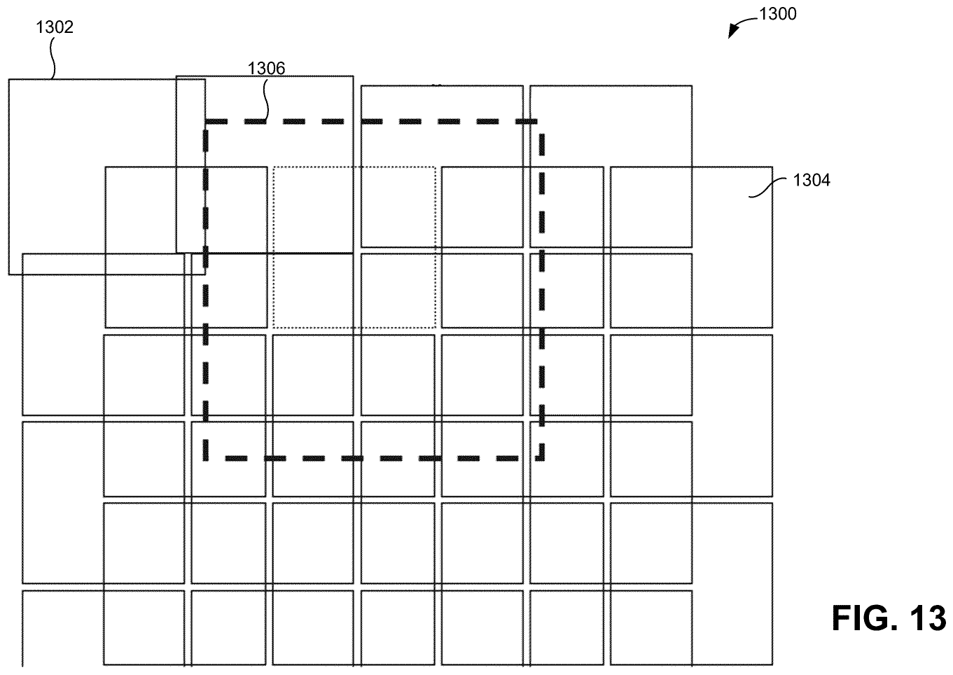

FIG. 13 shows a 50 percent pattern with oversized coils that overlap fellow coils within a same coil pattern. Coil 1302 is shown larger. In this case coils are more than half the size of the transmitting coil only the top left two receiving coils are oversized however in various embodiments some or all of the other coils, including the shifted pattern could be oversized. Inductor patterns 1304 and 1304 are again shifted by 50% in both horizontal and vertical directions to provide flexibility in identifying a relatively centered coil within the transmitting coil 1306 which evidences a significant misalignment. In this case, the center coil shown with a partially dashed line is relatively centered within coil 1306 and therefore would be a good candidate receiving coil to be selected to receive a signal from a transmitting device such as a memory cube.

FIG. 14 shows a less than 50 percent pattern with oversized coils that overlap fellow coils within a same coil pattern. Coils 1402 and 1404 are shown larger than half the width of the transmitting coil 1406. In this case, the center coil shown with a partially dashed line is relatively centered within coil 1406 and therefore would be a good candidate receiving coil to be selected to receive a signal from a transmitting device such as a memory cube.

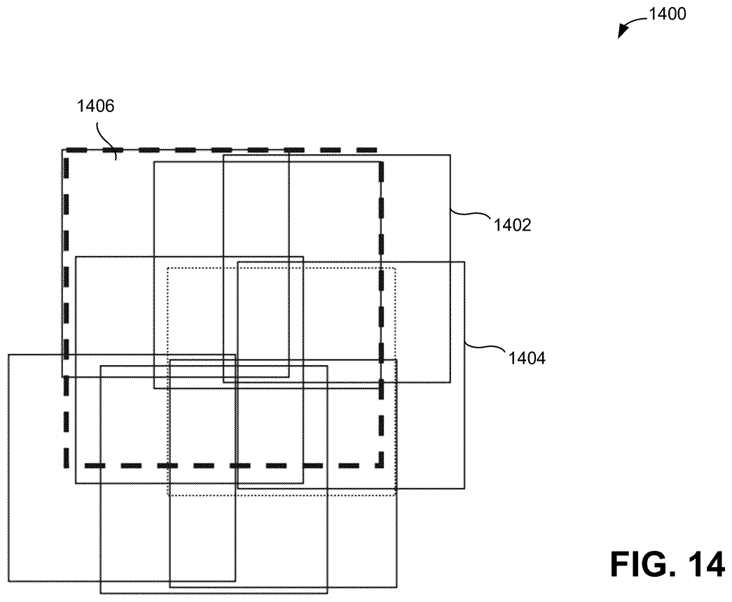

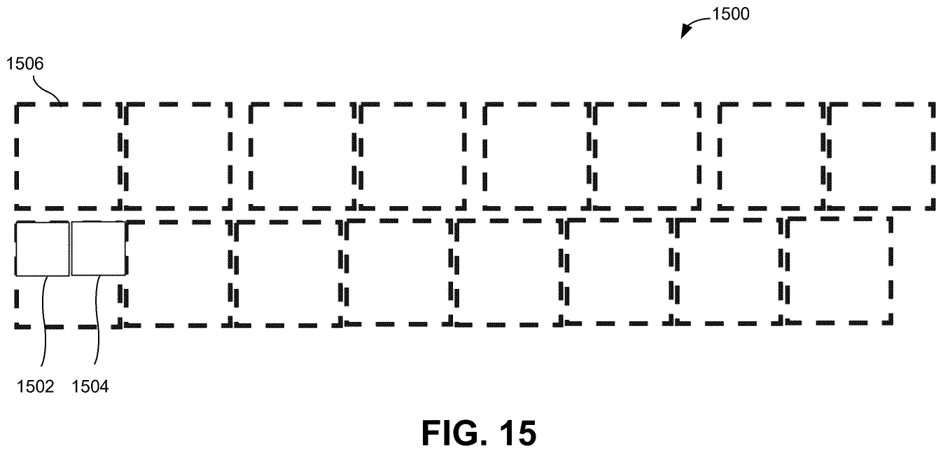

FIG. 15 illustrates an exaggerated layout in which the various inductors 1506 in a particular slice may not be uniform in a cube across slices or even within a slice. Receiving coils may be emplaced as set forth above to find a centered receiving coil on a transmit coil-by-coil basis.

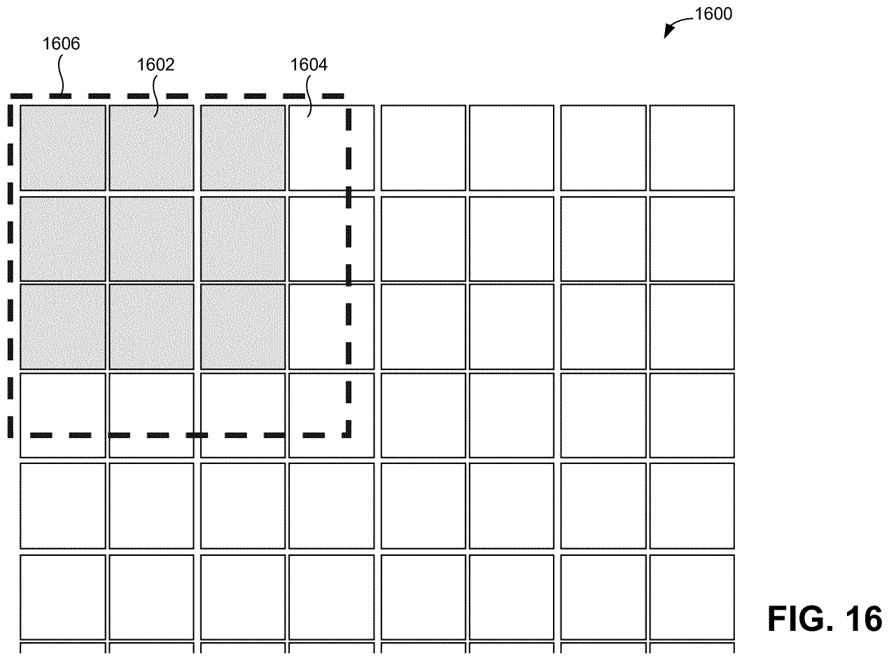

FIG. 16 shows further arrangements of smaller diameter coils 1602 on a host substrate that can be selectively activated to transmit to a larger diameter coil 1606 in another integrated circuit such as a three-dimensional memory cube. In this case, it may be cost wasteful to make smaller coils on a memory cube for the purpose of overcoming misalignments, in this case the transmitting host platform may selectively energize a group of coils, i.e., the grey-shaded coils 1602 (which may be referred to as sub-inductors) while not energizing the coils 1604 that lie outside of the receiving coil 1606. In some embodiments, a host platform transmits by way of the host substrate a series of predefined addresses which addresses return a signal strength at a particular inductor. The signal strength may be measured within the integrated circuit for example by way of an analog to digital converter. In this way, the host platform may select sub-inductors to use based on a received signal strength received in the various coils of the semiconductor.

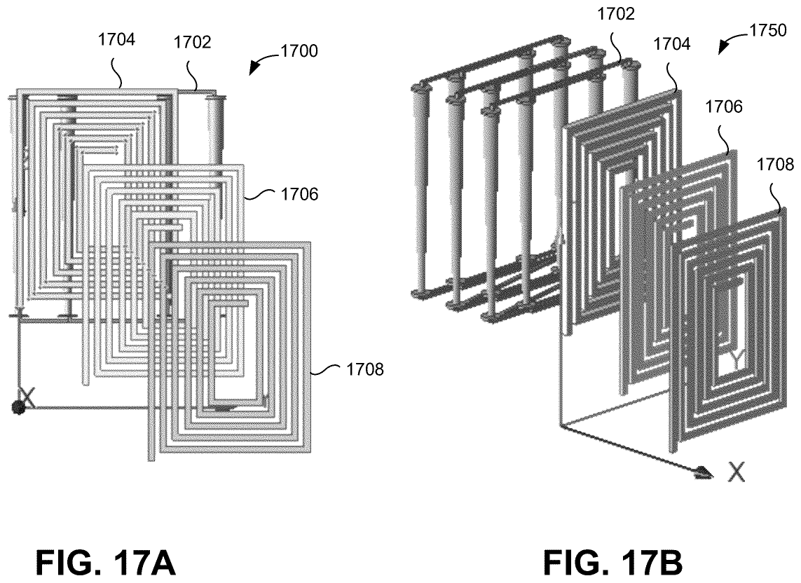

FIG. 17A shows a two-dimensional rendering 1700 of an exemplary formation of inductor coils 1702 using through silicon vias and vertical inductors that can be used use as a platform-to-chip interface to communicate with three-dimensional integrated circuits with offset inductors 1704, 1706, and 1708 in a planar host die. FIG. 17B shows a three-dimensional rendering 1750 of an exemplary formation of inductor coils 1702 using through silicon vias and vertical inductors that can be used use as a platform-to-chip interface to communicate with three-dimensional integrated circuits with offset inductors 1704, 1706, and 1708 in a planar host die. In various aspects, arrangements of offset-positioned coils may be coupled with one or more corresponding coils in a matching three-dimensional chip. Even if a misaligned placement of a chip occurs, at least one of the offset coils (see e.g., coil 1704, 1706, 1708) will be properly positioned with respect to matching inductor coil 1702, which provides a robust inductive coupling. By selecting a strongest coupled coil of the offset-positioned coils, a channel will have enhanced reliability with relaxed alignment requirements for the coils of a wireless integrated circuit communication interface.

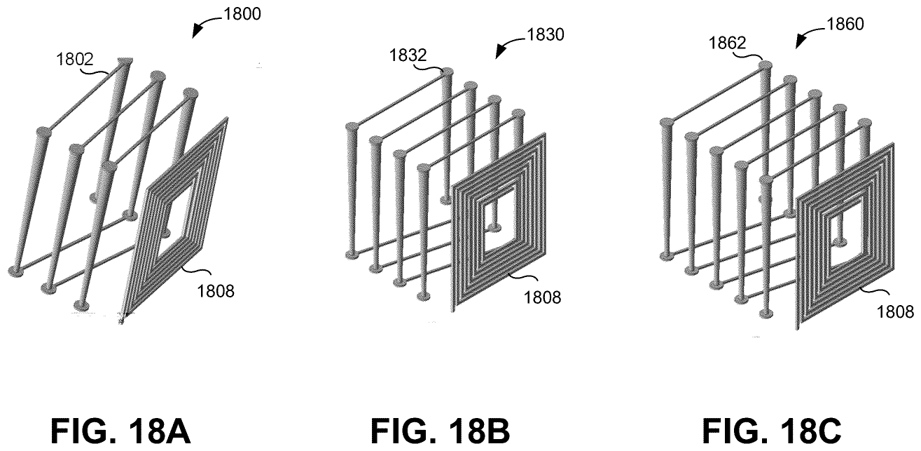

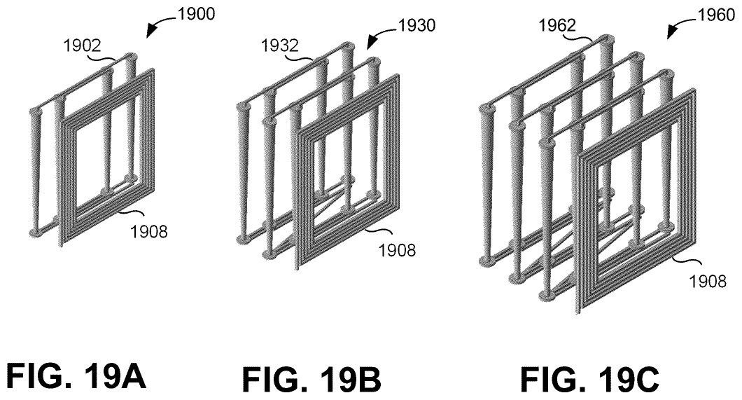

FIGS. 18A to 18B show three-dimensional renderings 1800, 1830, and 1860 of exemplary formations of inductor coils 1802, 1832, and 1862 using through silicon vias and vertical inductors that can be used use as a platform-to-chip interface to communicate with three-dimensional integrated circuits using coil inductors 1808 in connection with a planar host die. FIGS. 19A to 19C show three-dimensional renderings 1900, 1930, and 1960 of exemplary formation of inductor coils using through silicon vias and vertical inductors that can be used use as a platform-to-chip interface to communicate with three-dimensional integrated circuits using coil inductors 1908 in a planar host die.

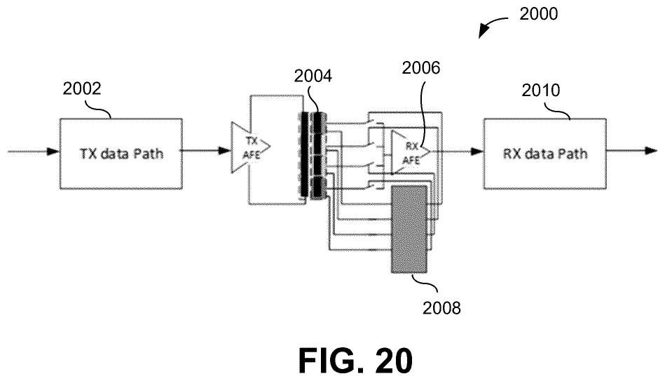

FIG. 20 shows a block diagram 2000 representing an exemplary mechanism for selecting a smaller coil in a receive-side inductive inter-chip communication system using a signal strength detect circuit 2008. Signal strength detect circuit 2008 measures an induced current in each of the small dimension coils in planar dies 2004 and compares a maximum current or voltage and identifies the coil that produced maximum induced current or voltage based on a signal from transmit data path 2002. Based on the detection of this max current or voltage the signal strength detector circuit selects the max strength coil and connects to receive analog front end 2006 and on to receive data path 2010.

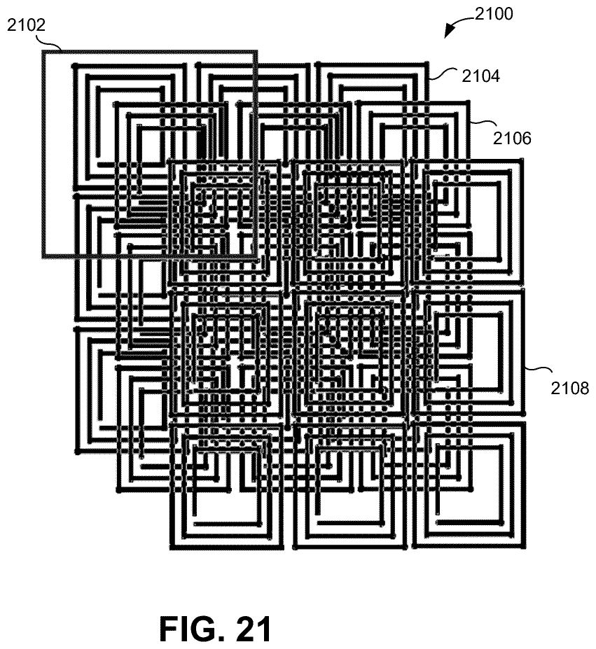

FIG. 21 shows a schematic diagram 2100 illustrating three layers of inductor coils 2104, 2106, and 2108 for use in connection with exemplary planar host die to communicate with an inductor 2102 in a three-dimensional integrated circuit. In various aspects, three layers of inductor coils may be provided in connection with a host die. Inductor 2102 represents a vertical inductor in a three-dimensional integrated circuit, such as for example a three-dimensional memory stack of memory chiplets. Inductor coils 2104, 2106, and 2108 represent various planar coils in metal layers of a planar host die. An improved signal strength detector circuit may be employed to identify a particular layer coil that is selected to connect to a receive-side analog front end to receive a higher-strength data signal from the vertical memory stack.

In various aspects, a magnetic field extends with an increasing depth of corresponding transmitting coils. Accordingly, a deeper solenoid-type structure may be employed for a transmitting coil to extend a corresponding magnetic field. In a vertical-dimension a number of via rows may be extended to increase a corresponding magnetic field, which facilitates an increased separation between two dies, while still exhibiting good communication characteristics. Similarly, a transmitting coil in a planar die may be also extended by adding coils in additional metal layers.

Unless explicitly specified, the term “transmit” encompasses both direct (point-to-point) and indirect transmission (via one or more intermediary points). Similarly, the term “receive” encompasses both direct and indirect reception.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “at least one” and “one or more” may be understood to include any integer number greater than or equal to one, i.e., one, two, three, four, [ . . . ], etc. The term “a plurality” or “a multiplicity” may be understood to include any integer number greater than or equal to two, i.e., two, three, four, five, [ . . . ], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The terms “processor” as used herein may be understood as any kind of technological entity that allows handling of data. The data may be handled according to one or more specific functions that the processor execute. Further, a processor as used herein may be understood as any kind of circuit, e.g., any kind of analog or digital circuit. A processor may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions may also be understood as a processor. It is understood that any two (or more) of the processors detailed herein may be realized as a single entity with equivalent functionality or the like, and conversely that any single processor detailed herein may be realized as two (or more) separate entities with equivalent functionality or the like.

The following examples pertain to aspects of the configuration proposed herein.

Example 1 is a device. The device includes a plurality of wafer stacks stacked adjacent one another, the plurality of wafer stacks including: a plurality of stacked semiconductor wafers; a logic base-die configured to support the plurality of stacked semiconductor wafers; and a plurality of through-semiconductor vias formed through the plurality of stacked semiconductor wafers and the logic base-die, wherein the plurality of through-semiconductor vias is configured to form a plurality of chip inductors configured to provide a communication interface to the plurality of stacked semiconductor wafers.

In Example 2, the subject matter of Example 1 may optionally include a host die including a plurality of host inductors.

In Example 3, the subject matter of Examples 1 or 2 may optionally include that the plurality of host inductors is configured to provide a communication interface between the host die and the plurality of wafer stacks.

In Example 4, the subject matter of Examples 1 to 3 may optionally include that the plurality of wafer stacks includes at least one dynamic random-access memory chiplet stack.

In Example 5, the subject matter of Examples 1 to 4 may optionally include a redistribution layer configured to connect a top and a bottom of the plurality of stacked semiconductor wafers.

In Example 6, the subject matter of Examples 1 to 5 may optionally include that the plurality of through-semiconductor vias includes: a plurality of rows of vias through the plurality of stacked semiconductor wafers, and wherein the redistribution layer connects a first pad associated with a first row of the plurality of rows of vias and a second pad associated with a second one of the plurality of rows of vias to form a first inductive loop of an inductive coil.

In Example 7, the subject matter of Examples 1 to 6 may optionally include that the plurality of through-semiconductor vias includes: a plurality of rows of vias through the plurality of stacked semiconductor wafers, and wherein the redistribution layer connects a first pad associated with a first row of the plurality of rows of vias and a second pad associated with a second row of the plurality of rows of vias through at least one redistribution layer landing via.

In Example 8, the subject matter of Examples 1 to 7 may optionally include that a checkerboard subset of a plurality of active coils is configured to communicate with the plurality of wafer stacks.

In Example 9, the subject matter of Examples 1 to 8 may optionally include a dummy coil connected to a dummy transmit or receive circuit, wherein a plurality of active coils is configured to perform a manufacturing loopback test to confirm proper functioning of at least one active coil in the plurality of active coils in connection with the dummy coil connected to the dummy transmit or receive circuit.

In Example 10, the subject matter of Examples 1 to 9 may optionally include a plurality of active inductors in the plurality of chip inductors is configured to perform a manufacturing loopback test to confirm proper functioning of a plurality of daisy chained active inductors in the plurality of active inductors.

Example 11 is a method of inter-chip communication. The method includes: receiving a predefined inductor signal pattern; activating, by way of a plurality of transmit analog front-end circuits, a plurality of corresponding transmit communication inductor coils of a three-dimensional semiconductor cube, the plurality of corresponding transmit communication inductor coils having a transmitting inductor width; receiving by way of a plurality of receive analog front-end circuits, a plurality of corresponding receive communication inductor signals at a plurality of receiving communication inductor coils at a host platform, wherein the plurality of receiving communication inductor coils have a receiving inductor width that is smaller than the transmitting inductor width; measuring a candidate signal strength of a candidate receive communication inductor signal in the plurality of corresponding receive communication inductor signals; and selecting a communication inductor for use in communication based on the candidate signal strength.

In Example 12, the subject matter of Example 11 may optionally include that the predefined inductor signal pattern is stored in a non-volatile memory within the three-dimensional semiconductor cube.

In Example 13, the subject matter of Examples 11 or 12 may optionally include that the three-dimensional semiconductor cube includes a plurality of dynamic random-access memory slices.

In Example 14, the subject matter of Example 11 may optionally include that the candidate signal strength is measured in the host platform as an induced current in a receive communication inductor using an analog to digital converter within the host platform.

Example 15 is a method for selectively activating sub-inductors in a host platform to facilitate communication between the host platform and potentially misaligned three-dimensional semiconductor devices. The method includes: receiving a predefined inductor signal pattern and an associated mapping of addresses; activating, by way of a plurality of transmit analog front-end circuits, a plurality of corresponding transmit communication inductor coils of a three-dimensional semiconductor cube, the plurality of corresponding transmit communication inductor coils including a plurality of transmitting sub-inductors; receiving by way of a plurality of receive analog front-end circuits, a plurality of corresponding receive communication inductor signals at a plurality of receiving communication inductor coils at a three-dimensional semiconductor device in the potentially misaligned three-dimensional semiconductor devices; looking up in the associated mapping of addresses an identification of a candidate communication inductor; measuring a candidate signal strength of a candidate communication inductor signal in the plurality of corresponding receiving communication inductor signals; transmitting a signal-strength output pattern plurality of transmit analog front-end circuits; and selecting a communication inductor for use in communication based on the candidate signal strength.

In Example 16, the subject matter of Example 15 may optionally include that the predefined inductor signal pattern is stored in a non-volatile memory within the host platform and the three-dimensional semiconductor cube.

In Example 17, the subject matter of Example 15 may optionally include that the three-dimensional semiconductor cube includes a plurality of dynamic random-access memory slices.

In Example 18, the subject matter of Examples 16 or 17 may optionally include that the candidate signal strength is measured in the three-dimensional semiconductor cube as an induced current in a receive communication inductor using an analog to digital converter within the three-dimensional semiconductor cube.

In Example 19, the subject matter of Example 15 may optionally include that the determining that at least one in the plurality of corresponding transmit communication inductor coils or the plurality of corresponding receiving communication inductor coils is defective; and storing a mapping of defective communication inductor coils.

In Example 20, the subject matter of Example 15 may optionally include: selectively disabling the defective communication inductor coils based on the mapping.

Example 21 is a device. The device includes: a plurality of stacked semiconductor wafers forming a wafer stack; a logic base die configured to support the plurality of stacked semiconductor wafers; and a plurality of through-semiconductor vias formed through the plurality of stacked semiconductor wafers, wherein the plurality of through-semiconductor vias is configured to form a plurality of inductive coils that is configured to provide a communication interface to the plurality of stacked semiconductor wafers.

In Example 22, the subject matter of Example 21 may optionally include that the plurality of stacked semiconductor wafers includes at least one dynamic random-access memory chiplet.

In Example 23, the subject matter of Examples 21 or 22 may optionally include: forming a redistribution layer configured to connect a top and a bottom of the plurality of stacked semiconductor wafers.

In Example 24, the subject matter of Examples 21 to 23 may optionally include that the at least one through silicon via includes a row of vias through the plurality of stacked semiconductor wafers, and wherein the redistribution layer connects a first pad associated with a first one of the row of vias and a second pad associated with a second one of the row of vias to form a first inductive loop of the inductive coil.

In Example 25, the subject matter of Examples 21 to 24 may optionally include that the at least one through silicon via includes a row of vias through the plurality of stacked semiconductor wafers, and wherein the redistribution layer connects a first pad associated with a first one of the row of vias and a second pad associated with a second one of the row of vias through at least one redistribution layer landing via and redistribution layer lateral interconnections on top of the vertical via pad.

In Example 26, the subject matter of Examples 23 to 25 may optionally include that the at least one through silicon via includes a plurality of rows of vias through the plurality of stacked semiconductor wafers, and wherein the redistribution layer connects a first pad associated with a first one of the row of vias and a second pad associated with a second one of the row of vias to form a multiturn inductive loop of the inductive coil.

In Example 27, the subject matter of Examples 21 to 26 may optionally include that the at least one through silicon via includes a plurality of rows of vias through the plurality of stacked semiconductor wafers, and wherein the redistribution layer includes at least one redistribution layer trace configured to connect a first pad associated with a first one of the row of vias and a second pad associated with a second one of the row of vias to form a first inductive loop of the inductive coil.

Example 28 is a device. The device includes: a host die; and a plurality of wafer stacks supported by the host die to form a composite semiconductor device, the wafer stacks stacked adjacent one another and each including: a plurality of stacked semiconductor wafers forming a wafer stack; and a logic base-die configured to support the plurality of stacked semiconductor wafers, wherein a plurality of through silicon vias is formed through the plurality of stacked semiconductor wafers is configured to form a plurality of inductive coils, configured to provide a communication interface to the plurality of stacked semiconductor wafers, and wherein the host die is configured to communicate with the plurality of wafer stacks by way of the plurality of inductive coils.

In Example 29, the subject matter of Example 28 may optionally include that a checkerboard subset of the plurality of active coils is configured to communicate with the plurality of wafer stacks.

In Example 30, the subject matter of Examples 28 or 29 may optionally include that a dummy coil connected to a dummy transmit and/or receive circuit, wherein the plurality of active coils is configured to perform a manufacturing loopback test to confirm proper functioning of at least one active coil in the plurality of active coils in connection with the dummy coil connected to the dummy transmit and/or receive circuit.

In Example 31, the subject matter of Examples 28 to 30 may optionally include that the plurality of active coils is configured to perform a manufacturing loopback test to confirm proper functioning of a plurality of daisy chained active coils in the plurality of active coils.

Example 32 is a device. The device includes: a processor; an interface substrate; and a plurality of composite semiconductor devices each including: a host die; and a composite semiconductor device including a plurality of wafer stacks, the wafer stacks including: a plurality of stacked semiconductor wafers forming a wafer stack; and a logic base-die configured to support the plurality of stacked semiconductor wafers, wherein a plurality of through silicon vias is formed through the plurality of stacked semiconductor wafers is configured to form at least one inductive coil, the at least one inductive coil configured to provide a communication interface to the plurality of stacked semiconductor wafers, wherein the host die is configured to communicate with the plurality of wafer stacks by way of the inductive coil, and wherein the interface substrate is configured to enable the processor to communicate with the plurality of composite semiconductor devices by way of the at least one inductive coil.

In Example 33, the subject matter of Example 32 may optionally include that the interface substrate is glass.

In Example 34, the subject matter of Examples 32 or 33 24 may optionally include at least one connector configured to provide power and input/output signals to the processor.

Example 35 is a method for loop-back testing communication inductors in semiconductor chiplets. The method includes: forming a first semiconductor element on a first semiconductor chiplet, the first semiconductor chiplet including a first communication inductor coil in communication with the first semiconductor element; forming a second semiconductor element on a second semiconductor chiplet, the second semiconductor chiplet including a second communication inductor coil in communication with the second semiconductor element; transmitting an electrical signal from the first communication inductor coil to the second communication inductor coil; receiving a signal at the second communication inductor coil; and determining that the first or second communication inductor coil is defective based on the signal.

In Example 36, the subject matter of Example 35 may optionally include that the first and second semiconductor elements are dynamic random-access memory cells.

In Example 37, the subject matter of Examples 35 or 36 may optionally include that the first and second communication inductor coils are formed in connection with through-semiconductor vias and metal layer traces.

In Example 38, the subject matter of Examples 35 to 37 may optionally include that the first and second communication inductors are positioned adjacent to one another within a reticle in a mirror-image configuration.

Example 39 is a method for bypassing defective communication inductors in semiconductor cubes, the method including: receiving a predefined inductor signal pattern; activating, by way of a plurality of transmit analog front-end circuits, a plurality of corresponding transmit communication inductor coils; receiving by way of a plurality of receive analog front-end circuits, a plurality of corresponding receive communication inductor signals at a plurality of receiving communication inductor coils; determining that at least one in the plurality of corresponding transmit communication inductor coils or the plurality of corresponding receive communication inductor coils is defective; storing a mapping of defective communication inductor coils; and selectively abstaining from using the defective communication inductor coils based on the mapping.

In Example 40, the subject matter of Example 39 may optionally include that the mapping is stored in a non-volatile memory external to the semiconductor cube.

In Example 41, the subject matter of Examples 39 or 40 may optionally include that the semiconductor cube is a cube of dynamic random-access memory slices.

In Example 42, the subject matter of Examples 39 to 41 may optionally include that the plurality of receiving communication inductor coils include at least one dummy receiving coil.

Example 43 is a method for determining a communication path between misaligned devices. The method includes: receiving a predefined inductor signal pattern; activating, by way of a plurality of transmit analog front-end circuits, a plurality of corresponding transmit communication inductor coils of a three-dimensional semiconductor cube, the plurality of corresponding transmit communication inductor coils having a transmitting inductor width; receiving by way of a plurality of receive analog front-end circuits, a plurality of corresponding receive communication inductor signals at a plurality of receiving communication inductor coils at a host platform, wherein the plurality of receiving communication inductor coils have a receiving inductor width that is smaller than the transmitting inductor width; measuring a candidate signal strength of a candidate receive communication inductor signal in the plurality of corresponding receive communication inductor signals; and selecting a communication inductor for use in communication based on the candidate signal strength.

In Example 44, the subject matter of Example 43 may optionally include that the predefined signal pattern is stored in a non-volatile memory within the three-dimensional semiconductor cube.

In Example 45, the subject matter of Examples 43 or 44 may optionally include that the three-dimensional semiconductor cube includes a plurality of dynamic random-access memory slices.

In Example 46, the subject matter of Examples 43 to 45 may optionally include that the candidate signal strength is measured in the host platform as an induced current in a receive communication inductor using an analog to digital converter within the host platform.

Example 47 is a method for selectively activating sub-inductors in a host platform to facilitate communication between the host platform and potentially misaligned three-dimensional semiconductor devices. The method includes: receiving a predefined inductor signal pattern and an associated mapping of addresses; activating, by way of a plurality of transmit analog front-end circuits, a plurality of corresponding transmit communication inductor coils of a three-dimensional semiconductor cube, the plurality of corresponding transmit communication inductor coils including a plurality of transmitting sub-inductors; receiving by way of a plurality of receive analog front-end circuits, a plurality of corresponding receive communication inductor signals at a plurality of receiving communication inductor coils at a three-dimensional semiconductor device in the potentially misaligned three-dimensional semiconductor devices; looking up in the mapping of addresses an identification of a candidate receive communication inductor; measuring a candidate signal strength of the candidate receive communication inductor signal in the plurality of corresponding receive communication inductor signals; transmitting a signal-strength output pattern plurality of transmit analog front-end circuits; and selecting a communication inductor for use in communication based on the candidate signal strength.

In Example 48, the subject matter of Example 47 may optionally include that the predefined signal pattern is stored in a non-volatile memory within the host platform and the three-dimensional semiconductor cube.

In Example 49, the subject matter of Examples 47 or 48 may optionally include that the three-dimensional semiconductor cube includes a plurality of dynamic random-access memory slices.

In Example 50, the subject matter of Examples 47 to 49 may optionally include that the candidate signal strength is measured in the three-dimensional semiconductor cube as an induced current in a receive communication inductor using an analog to digital converter within the three-dimensional semiconductor cube.

What is claimed is:

1. A device comprising:
a plurality of wafer stacks stacked adjacent one another, the plurality of wafer stacks comprising:
a plurality of stacked semiconductor wafers;
a logic base-die configured to support the plurality of stacked semiconductor wafers; and
a plurality of through-semiconductor vias formed through the plurality of stacked semiconductor wafers and the logic base-die,
wherein the plurality of through-semiconductor vias is configured to form a plurality of chip inductors configured to provide a communication interface to the plurality of stacked semiconductor wafers.

2. The device of claim 1 further comprising: a host die comprising a plurality of host inductors.

3. The device of claim 2, wherein the plurality of host inductors is configured to provide a communication interface between the host die and the plurality of wafer stacks.

4. The device of claim 1, wherein the plurality of wafer stacks comprises at least one dynamic random-access memory chiplet stack.

5. The device of claim 1 further comprising: a redistribution layer configured to connect a top and a bottom of the plurality of stacked semiconductor wafers.

6. The device of claim 5, wherein the plurality of through-semiconductor vias comprises: a plurality of rows of vias through the plurality of stacked semiconductor wafers, and wherein the redistribution layer connects a first pad associated with a first row of the plurality of rows of vias and a second pad associated with a second one of the plurality of rows of vias to form a first inductive loop of an inductive coil.

7. The device of claim 5, wherein the plurality of through-semiconductor vias comprises: a plurality of rows of vias through the plurality of stacked semiconductor wafers, and wherein the redistribution layer connects a first pad associated with a first row of the plurality of rows of vias and a second pad associated with a second row of the plurality of rows of vias through at least one redistribution layer landing via.

8. The device of claim 1, wherein a checkerboard subset of a plurality of active coils is configured to communicate with the plurality of wafer stacks.

9. The device of claim 1 further comprising: a dummy coil connected to a dummy transmit or receive circuit, wherein a plurality of active coils is configured to perform a manufacturing loopback test to confirm proper functioning of at least one active coil in the plurality of active coils in connection with the dummy coil connected to the dummy transmit or receive circuit.

10. The device of claim 1, wherein a plurality of active inductors in the plurality of chip inductors is configured to perform a manufacturing loopback test to confirm proper functioning of a plurality of daisy chained active inductors in the plurality of active inductors.

11. A method of inter-chip communication comprising:
receiving a predefined inductor signal pattern;
activating, by way of a plurality of transmit analog front-end circuits, a plurality of corresponding transmit communication inductor coils of a three-dimensional semiconductor cube, the plurality of corresponding transmit communication inductor coils having a transmitting inductor width;
receiving by way of a plurality of receive analog front-end circuits, a plurality of corresponding receive communication inductor signals at a plurality of receiving communication inductor coils at a host platform, wherein the plurality of receiving communication inductor coils have a receiving inductor width that is smaller than the transmitting inductor width;
measuring a candidate signal strength of a candidate receive communication inductor signal in the plurality of corresponding receive communication inductor signals; and
selecting a communication inductor for use in communication based on the candidate signal strength.

12. The method of claim 11, wherein the predefined inductor signal pattern is stored in a non-volatile memory within the three-dimensional semiconductor cube.

13. The method of claim 11, wherein the three-dimensional semiconductor cube comprises a plurality of dynamic random-access memory slices.

14. The method of claim 11, wherein the candidate signal strength is measured in the host platform as an induced current in a receive communication inductor using an analog to digital converter within the host platform.

15. A method for selectively activating sub-inductors in a host platform to facilitate communication between the host platform and potentially misaligned three-dimensional semiconductor devices, the method comprising:
receiving a predefined inductor signal pattern and an associated mapping of addresses;
activating, by way of a plurality of transmit analog front-end circuits, a plurality of corresponding transmit communication inductor coils of a three-dimensional semiconductor cube, the plurality of corresponding transmit communication inductor coils comprising a plurality of transmitting sub-inductors;
receiving by way of a plurality of receive analog front-end circuits, a plurality of corresponding receive communication inductor signals at a plurality of receiving communication inductor coils at a three-dimensional semiconductor device in the potentially misaligned three-dimensional semiconductor devices;
looking up in the associated mapping of addresses an identification of a candidate communication inductor;
measuring a candidate signal strength of a candidate communication inductor signal in the plurality of corresponding receiving communication inductor signals;
transmitting a signal-strength output pattern plurality of transmit analog front-end circuits; and
selecting a communication inductor for use in communication based on the candidate signal strength.

16. The method of claim 15, wherein the predefined inductor signal pattern is stored in a non-volatile memory within the host platform and the three-dimensional semiconductor cube.

17. The method of claim 15, wherein the three-dimensional semiconductor cube comprises a plurality of dynamic random-access memory slices.

18. The method of claim 15, wherein the candidate signal strength is measured in the three-dimensional semiconductor cube as an induced current in a receive communication inductor using an analog to digital converter within the three-dimensional semiconductor cube.

19. The method of claim 15 further comprising:
determining that at least one in the plurality of corresponding transmit communication inductor coils or the plurality of corresponding receiving communication inductor coils is defective; and
storing a mapping of defective communication inductor coils.

20. The method of claim 19 further comprising:
selectively disabling the defective communication inductor coils based on the mapping.
